(19) United States
(12) Patent Application Publication
(10) Pub. No.: US 2012/0208114 A1
(43) Pub. Date: Aug. 16, 2012

(54) PIGMENT COMPOSITION CONTAINING PYRIMIDINES AND DERIVATIVES THEREOF

(75) Inventors: Soon Hyun Park, Gyeonggi-do (KR); Go Hyeon Kim, Gyeonggi-do (KR)

(73) Assignee: Kyung-In Synthetic Corporation, Seoul (KR)

(21) Appl. No.: 13/503,821

(22) PCT Filed: Dec. 9, 2010
(86) PCT No.: PCT/KR2010/008781

§ 371 Date: Apr. 24, 2012

(30) Foreign Application Priority Data
Dec. 24, 2009 (KR) 10-2009-0130516

(51) Int. Cl. G03F 7/20; G03F 7/032; C09B 29/52; C08K 5/23

(52) U.S. Cl. 430/7; 106/496; 430/283.1; 534/767

(57) ABSTRACT

Disclosed is a pigment composition comprising a metal complex of azo compound of formula 1 containing at least one pyrimidine or a pyrimidine derivative. The pigment composition exhibits improved color characteristics, improved stability and easy dispersion.

### TECHNICAL FIELD

The present invention relates to a pigment composition. More specifically, the present invention relates to a pigment composition comprising a metal complex of an azo compound containing pyrimidine or a pyrimidine derivative as a guest compound, thus exhibiting improved color characteristics as well as improved stability and superior dispersibility.

### BACKGROUND ART

Pigment compositions have been used for inks, paints and the like. In accordance with recent advances in IT, pigment compositions are generally used for color filters and the like. Color filters are generally used for liquid crystal displays, screens, color separation apparatuses, sensors and the like. LCD monitors or TVs are well-known.

There are various methods for manufacturing color filters. There are differences between these methods in terms of color-application methods as well as formation of pixel patterns with primary colors (red, green and blue), or black. For example, color can be rendered by a coloring method (“dying method”, “dye dispersion method”) of base layers composed of soluble dyes or pigments (such as gelatin), screen printing, offset printing or inkjet printing of pigment pastes, preparations or inks, electrochemical deposition of photoresists containing a dye or pigment as a base material, and in particular, pigment dispersion methods using pigments dispersed in polyimide resins (“non-photosensitive polyimide method”) or photoresists (“photosensitive acrylic acid method”). Regarding the afore-mentioned methods, both a method for directly forming pixel patterns by printing, and indirect photolithography are important, and in particular, among the pigment dispersion methods, photolithography is more important. “Non-photosensitive polyimide method”-type pigment dispersion methods are disclosed in Japanese Patent Application Publication No. 1998-22392 and the like.

Regarding pigment dispersion methods, use of pigments has advantages in that resistance to light, moisture and heat of color filters are improved as compared to dye-based coating systems. However, transparency and color purity of pigment-based coatings are unsatisfactory regardless of coating methods and, in particular, undesired loss in luminosity and transparency are involved when various pigments mixed to match the desired color locus value are incorporated into a photoresist and, as a result, energy requirements of LCDs and the like are increased.

Pigments used in the color filter field are disclosed in Japanese Patent Application Publication Nos. 1998-22392 (Toray), 1998-19183 (Hitachi); Specific Pigment Colour Index Pigment Yellow 150), and 1998-19184 (Hitachi) and the like, but improvement in the requirements is required.

In order to solve these pigments, Korean Patent Laid-open No. 2001-0095243 discloses a complex composed of an azo compound and a metal such as Li, Cs, Mg, Cd, Co, Al, Cr, Sn, and Pb, and in particular, a metal complex containing melamine, a melamine derivative or a condensation polymer as a guest compound.

However, in spite of efforts for improvement, color filters having better color characteristics for next-generation displays and the like are still required. For this reason, there is an increasing need for development of pigments with color characteristics as well as improved stability and easy dispersability.

### DISCLOSURE

### Technical Problem

Therefore, the present invention has been made to solve the above problems and other technical problems that have yet to be resolved.

As a result of a variety of extensive and intensive studies and experiments to solve the problems as described above, the inventors of the present invention have developed a pigment composition comprising a metal complex of an azo compound containing pyrimidine or a pyrimidine derivative as a guest compound, and discovered that improved color characteristics can be obtained, stability is improved and dispersion is easy, as compared to conventional cases, when the pigment composition is used. Based on this discovery, the present invention has been completed.

### Technical Solution

In accordance with one aspect of the present invention, provided is a pigment composition comprising a metal complex of an azo compound of formula 1 below containing at least one pyrimidine or pyrimidine derivative as a guest compound:

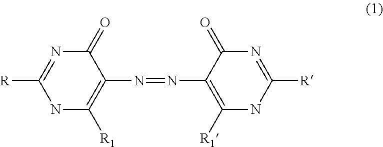

wherein R and R′ each independently represent OH, NH₂, NH—CN, acylamino or arylamino, and R₁ and R₁′ each independently represent —OH or —NH₂.

According to the present invention, the metal complex of the azo compound of formula 1 comprises at least one pyrimidine or pyrimidine derivative as a guest compound and the pigment composition exhibits improved color characteristics, improved stability and easy dispersion during manufacture of color filters and the like, as compared to conventional cases.

In a preferred embodiment, the pyrimidine or pyrimidine derivative may be a compound of formula 2 below:

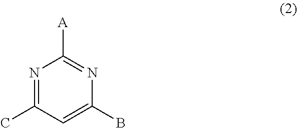

wherein A, B and C each independently represent C₁-C₅ alkyl, phenyl, —OH, —SH, —SOOH, —COOH, —NRR′, —O—R, or —O-Ph in which R and R′ each independently represent hydrogen, C₁-C₅ alkyl or C₄-C₆ aryl.

Of these, a pyrimidine or pyrimidine derivative of formula 3 below is particularly preferred.

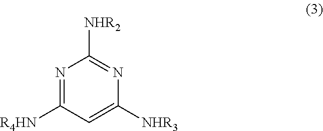

wherein R₂ to R₄ each independently represent hydrogen, C₁-C₄ alkyl or phenyl.

Particularly preferably, R₂ to R₄ each represent hydrogen, since hydrogen bonding can be formed well in a metal complex.

The pyrimidine or pyrimidine derivative is preferably contained in an amount of 5 to 300 parts by weight, more preferably, 10 to 200 parts by weight, based on 100 parts by weight of the metal complex excluding the guest compound.

The pigment composition according to the present invention can be prepared by incorporating a process for treating pyrimidine or a pyrimidine derivative into a conventional process for preparing a pigment composition.

Compounds and solids contained in the metal complex are known in the documents, and these substances and preparation methods thereof are disclosed in European Patent Application Nos. 0074515 and 0073463 and are mentioned in Organic pigment Handbook. These documents are incorporated herein by reference.

Specifically, various salts may be used alone or in combination thereof and metals or pigment compositions containing various metals can be obtained therefrom. An aqueous dispersion of the metal complex thus obtained was filtered, washed and dried. A drying method includes all methods of drying or spray-drying an aqueous slurry. The pigment composition thus obtained may be post-ground.

If necessary, the obtained pigment composition may be further treated by a method selected from various methods such as milling, kneading and ball-milling. In any step of preparing the pigment composition, the pyrimidine or pyrimidine derivative may be treated. Preferably, the pigment composition may be treated in a synthesis post-treatment or milling process.

The pigment composition according to the present invention preferably has a primary particle size measured using a scanning electron microscope, lower than 60 nm, in order to exhibit color characteristics, stability and dispersability suitable for color filters. In particular, the primary particle size is more preferably lower than 40 nm.

The pigment composition of the present invention may be mixed with other pigments. Other pigments that can be mixed may be inorganic or organic pigments. Examples of preferred organic pigments include monoazo, diazo, lakeazo, betanaphthol, naphthol AS, benzimidazolone, condensed diazo compounds, azometal complexes, isoindoline and isoindolinone pigments or polycyclic pigments such as phthalocyanine, quinacrine, perylene, rerinon, thioindigo, anthraquinone, dioxazine, quinophthalone and diketopyrrolopyrrole and the like. Lake dyes such as Ca, Mg and Al lakes of sulfo- or carboxyl-containing pigments may also be used.

Specific examples of the organic pigment include the following color index pigments:

Color index pigment yellow 12, 13, 14, 17, 20, 24, 74, 83, 86, 93, 94, 109, 110, 117, 125, 137, 138, 139, 147, 148, 150, 153, 154, 166, 173, 185 and the like;

Color index pigment orange 13, 31, 36, 38, 40, 42, 43, 51, 55, 59, 61, 64, 65, 71, 72, 73, and the like;

Color index pigment red 9, 97, 122, 123, 144, 149, 166, 168, 177, 180, 192, 215, 216, 224, 254, 255, 272, and the like;

Color index pigment green 7, 10, 36, 37, 45, 58, and the like;

Color index pigment blue 1, 15, 15:1, 15:2, 15:3, 15:4, 15:6, 16, 60 and the like; or

Color index pigment violet 19, 23 and the like.

As mentioned above, when another pigment is further added, the content of metal complex according to the present invention is preferably 1 to 99% by weight, more preferably 5 to 80% by weight, based on the total amount of all pigments including another pigment.

The pigment composition according to the present invention is generally useful for all applications of pigments. In particular, the pigment composition of the present invention is preferably used for color filters.

When color filters are produced using the pigment composition of the present invention, at least one organic solvent, binder and/or dispersant may be further contained.

Examples of the organic solvent include ketones, alkylene glycol ethers, alcohols and aromatic compounds. Ketones include acetone, methyl ethyl ketone, cyclohexanone and the like, alkylene glycol ethers include methylcellosolve(ethylene glycol monomethyl ether), butylcellosolve(ethylene glycol monobutyl ether), methylcellosolve acetate, ethylcellosolve acetate, butylcellosolve acetate, ethylene glycol monopropyl ether, ethylene glycol monohexyl ether, ethylene glycol dimethyl ether, diethylene glycol ethyl ether, diethylene glycol diethyl ether, propylene glycol monomethyl ether, propylene glycol monoethyl ether, propylene glycol monopropyl ether, propylene glycol monobutyl ether, propylene glycol monomethyl ether acetate, diethylene glycol methyl ether acetate, diethylene glycol ethyl ether acetate, diethylene glycol propyl ether acetate, diethylene glycol isopropyl ether acetate, diethylene glycol butyl ether acetate, diethylene glycol t-butyl ether acetate, triethylene glycol methyl ether acetate, triethylene glycol ethyl ether acetate, triethylene glycol propyl ether acetate, triethylene glycol isopropyl ether acetate, triethylene glycol butyl ether acetate, triethylene glycol t-butyl ether acetate and the like; and alcohols include methyl alcohol, ethyl alcohol, isopropyl alcohol, n-butyl alcohol, 3-methyl-3-methoxybutanol and the like; aromatic solvents include benzene, toluene, xylene, N-methyl-2-pyrrolidone, ethyl N-hydroxymethylpyrrolidone-2 acetate and the like. Examples of other solvents include 1,2-propanediol diacetate, 3-methyl-3-methoxybutyl acetate, ethyl acetate, tetrahydrofuran and the like. These solvents may be used alone or in combination thereof.

Any binder may be used without particular limitation so long as it is a resin capable of providing adhesion, and a known film-forming resin is useful.

Useful examples include cellulose resins, in particular, carboxymethylhydroxyethyl cellulose and hydroxyethyl cellulose, acrylic acid resins, alkyd resins, melamine resins, epoxy resins, polyvinyl alcohols, polyvinylpyrrolidone, polyamide, polyamide-imine, and polyimide binders and the like.

Useful binders include resins having a photopolymerizable unsaturated bond and may for example be acrylic acid resin binders. In particular, useful binders include polymers and copolymers of polymerizable monomers, such as methyl(meth)acrylate, ethyl(meth)acrylate, propyl(meth)acrylate, butyl(meth)acrylate, styrene and styrene derivatives, carboxy-containing polymerizable monomers such as (meth)acrylic acid, itaconic acid, maleic acid, maleic anhydride, monoalkyl meleate (in particular, alkyl having 1 to 12 carbon atoms), and copolymers of polymerizable monomers such as (meth)acrylic acid, styrene and styrene derivatives (for example, α-methylstyrene, m- or p-methoxystyrene, or p-hydroxystyrene).

Specific examples include reaction products of compounds containing oxylane rings and ethylene-based unsaturated compounds (for example, glycidyl(meth)acrylate, acryloyl glycidyl ether and monoalkyl glycidyl itaconate and the like) and carboxy-containing polymer compounds, and reaction products of compounds containing a hydroxyl group and ethylene-based unsaturated compounds (unsaturated alcohol) (for example, allyl alcohol, 2-buten-4-ol, oleyl alcohol, 2-hydroxyethyl(meth)acrylate, N-methylolacrylamide and the like) and carboxy-containing polymer compounds. This binder may contain an unsaturated compound having no isocyanate group.

Equivalents of unsaturation degree of the binder (molecular weight of binder per unsaturated compound) may be generally in a range of 200 to 3,000, in particular 230 to 1,000 to provide suitable photopolymerization properties and film hardness. After film exposure, the binder may have an acid value of 20 to 300, in particular, 40 to 200, to provide sufficient alkali developing properties.

The binder has an average molecular weight of 1,500 to 200,000, in particular, 10,000 to 50,000 g/mol.

The dispersant is not particularly limited, but well-known dispersants include cationic, anionic, amphoteric, zwitterionic or neutral nonionic dispersants and the like. Preferred examples of anionic dispersants include alkylbenzene-sulfonate, alkylnaphthalene-sulfonate, alkylsulfosuccinate, or naphthalene formaldehyde sulfonate and the like, preferred examples of cationic dispersants include benzyl tributyl ammonium chlorides and the like, and preferred examples of amphoteric or nonionic dispersants include polyoxyethylene, alkyl or amidopropyl and the like.

These organic solvents, binders, dispersants and the like may be added within the range of the content well-known in the art as pigment compositions for color filters.

The present invention provides a photoresist having the following components:

(1) the pigment composition according to the present invention and optional at least one other pigment;

(2) at least one photocurable monomer;

(3) at least one photoinitiator;

(4) organic solvent;

(5) binder;

(6) optional dispersant; and

(7) optional further additive.

The optional other pigment may be an organic or inorganic pigment, as mentioned above, and the organic solvent, binder, optional dispersant and the like may be an organic solvent, a binder, a dispersant and the like, as mentioned above.

The photocurable monomer contains at least one reactive double bond and at least one additional reactive group in the molecule.

In this regard, useful photocurable monomers include in particular, reactive solvents or reactive diluents, for example, mono-, di-, tri- and multi-functional acrylate and methacylate, vinyl ether, glycidyl ether and the like. Additional reactive groups include allyl, hydroxyl, phosphate, urethane, secondary amine, N-alkoxymethyl groups and the like.

These monomers are known in the art and are described in [Roempp, Lexikon, Lacke und Druckfarben, Dr. Ulrich Zorll, Thieme Verlag Stuttgart-New York, 1998, p. 491/492], which is incorporated herein by reference. Selection of monomers, in particular, depends on the type and intensity of irradiation used, target reactions using a photoinitiator and film properties. These photocurable monomers may be used alone or in combination thereof.

The photoinitiator is for example a compound that forms reaction intermediates capable of inducing polymerization reaction of the monomers and/or binders, as a result of absorption of visible or ultraviolet light. The photoinitiator is also well-known in the art and is, for example, seen in [Roempp Lexikon, Lacke und Druckfarben, Dr. Ulrich Zorll, Thieme Verlag Stuttgart-New York, 1998, p. 445/446], which is incorporated herein by reference.

Any optionally added additive may be used without particular limitation so long as it satisfies the desired object. Preferred examples thereof include fatty acids, fatty amines, alcohols, bean oils, waxes, rosins, resins, benzotriazole derivatives and the like in order to improve surface texture. More preferably, useful fatty acids include stearic acid or behenic acid and the like and useful fatty amines include stearyl amine and the like.

The content ratio of components contained in the photoresist may be the same as that well-known in the art.

A method for forming color pixel patterns using the pigment or solid pigment preparations used for the present invention as a base material is not particularly limited. Accordingly, other methods such as photolithography as well as offset printing, chemical grinding or inkjet printing are also suitable. Selection of suitable binder and solvent or pigment transfer medium, and other additives should be carried out in accordance with the specific method. Inkjet methods including thermal inkjet printing as well as mechanical and pressure-mechanical inkjet printing use pigments and organic vehicle media as well as aqueous organic vehicle media that are pure with respect to any binder, and is preferably substantially an aqueous organic vehicle medium.

The present invention also provides a method for producing a color filter including the following processes:

(a) grinding the pigment composition according to the present invention in an organic solvent in the presence of a binder and a dispersant;

(b) treating the ground substance obtained in step (a) in the presence of a photocurable monomer, a photoreactive initiator, a binder and a solvent to form a photoresist;

(c) applying the photoresist to a substrate by a roller, spray, spin, dip or air knife coating method; and

(d) irradiating the substrate through a photomask, followed by curing and developing to form a color filter.

The substrate of step (c) is more preferably a glass substrate.

The production method enables formation of a color filter that can be further readily colored.

Accordingly, the present invention provides a color filter comprising the pigment composition and a display comprising at least one of the color filter.

### BEST MODE

Now, the present invention will be described in more detail with reference to the following examples. These examples are provided only to illustrate the present invention and should not be construed as limiting the scope and spirit of the present invention.

### EXAMPLE 1

20 g of benzenesulfonyl hydrazide, 400 ml of water, and 30 ml of 10N hydrochloric acid were stirred for 30 minutes. After addition of ice, 34 ml of sodium nitrite containing 30 g of sodium nitrate in 100 ml of the solution was added dropwise over 30 minutes. The mixture was stirred over 30 minutes while maintaining excess nitrite. Then, excess nitrite was decomposed with a small amount of aminosulfonic acid, and a batch was neutralized with 5 ml of a ION aqueous sodium hydroxide solution to provide an emulsion. The emulsion thus adjusted was mixed with 40 mL of barbituric acid, stirred for 10 minutes and adjusted with about 33 ml of a lON aqueous sodium hydroxide solution to a pH of 8. The mixture was stirred at 50° C. for 2 hours, stirred, adjusted to a pH of 4.8 with 3 ml of acetic acid and 14 ml of 10N hydrochloric acid, and then heated at 70° C. for one hour and heated at 80° C. for 3 hours to prepare a suspension of sodium azobarbiturate acid. The suspension thus prepared was heated at 95 to 100° C., filtered under suction and washed with about 1 liter of boiling water once to obtain a compressed cake of sodium azobarbiturate. The compressed cake thus prepared was stirred with 500 ml of water. A solution of 35 g of NiCl₂-6H₂O in 100 ml of water was added dropwise at 80° C. over 5 minutes. This mixture was stirred at 80° C. for one hour, mixed with 40 g of pyrimidine, further stirred at 80° C. for one hour and at 90° C. for 2 hours, filtered under suction at a warm temperature and washed with hot water. Through this process, a moisture pigment compressed cake having a solid content of 42.6% by weight was obtained. The cake was dried and ground to obtain a pigment.

### EXAMPLE 2

20% by weight of the pigment synthesized in Example 1, 20% by weight of glycol and 80% by weight of a crushed salt were added to a kneader and crushed at 120° C. for 12 hours, the crushed substance was added to 1000 ml of water, purified with acid, filtered, washed with water, dried and ground to obtain a pigment.

### COMPARATIVE EXAMPLE 1

25 g of benzenesulfonyl hydrazide, 200 ml of water, 20 ml of 10N hydrochloric acid and 1.25 g of a condensed product of taurine and stearic acid were stirred over 30 minutes. 60 g of ice was added to the mixture, and 34 ml of an anhydrous sodium nitrate solution containing 30 g of sodium nitrate in 100 ml of the solution was added dropwise over 30 minutes. The mixture was stirred over 30 minutes in the presence of excess nitrite. Then, the excess nitrite was decomposed with a small amount of aminosulfonic acid, and a batch was neutralized with 5 ml of a lON aqueous sodium hydroxide solution to provide an emulsion. The emulsion thus adjusted was mixed with 38.2 mL of barbituric acid, stirred for 10 minutes and adjusted with about 33 ml of a 10N aqueous sodium hydroxide solution to a pH of 8. The mixture was stirred at 50° C. for 2 hours, adjusted to pH of 4.8 with 3 ml of acetic acid and 14 ml of 10N hydrochloric acid, and then heated at 70° C. for one hour and heated at 80° C. for 3 hours to prepare a suspension of sodium azobarbiturate acid. The suspension thus prepared was heated at 95 to 100° C., filtered under suction and washed with about 1 liter of boiling water once to obtain a compressed cake of sodium azobarbiturate. The compressed cake thus prepared was stirred with 500 ml of water. A solution of 34.5 g of NiCl₂-6H₂O in 100 ml of water was added dropwise at 80° C. over 5 minutes. This mixture was stirred at 80° C. for one hour, mixed with 40 g of pyrimidine, further stirred at 80° C. for one hour and at 90° C. for 2 hours, filtered under suction at a warm temperature and washed with hot water. Through this process, a moisture pigment compressed cake having a solid content of 42.6% by weight was obtained. The cake was dried and ground to obtain a pigment.

### COMPARATIVE EXAMPLE 2

136 g of aminoguanidine bicarbonate was incorporated into 810 g of distilled water and was dissolved in 280 g of hydrochloric acid (30%). Then, this solution was cooled to about −10° C. with 780 g of ice and was then mixed with 232 g of 37% a potassium nitric acid solution in water until the temperature reached about 15° C. Then, this solution was stirred at 15° C. for 15 minutes and was then mixed with 2.0 g of amidosulfuric acid. 269 g of barbituric acid was added thereto, heated to 55° C. and then stirred for 2 hours. Then, the reaction solution was titrated to pH of 4.8 with an aqueous potassium hydroxide solution and then stirred for 30 minutes. Then, the reaction solution was heated to 80° C. and then stirred at pH of 4.8 for 3 hours. Subsequently, the reaction solution was separated in a suction filter, washed to remove an electrolyte, dried in an air circulation drying cabinet at 40° C. and ground to obtain a pigment.

### EXPERIMENTAL EXAMPLE

The following substances were added to a disperser and the disperser was operated for 5 hours to prepare a dispersion. The viscosity of the dispersion thus prepared was measured with a Brookfield viscosity meter (LVDV-III™, Brookfield Engineering). In order to measure color characteristics, the dispersion prepared above was coated depending on the film thickness according to coating rate and dried at 60 degrees for 30 minutes. In order to measure optical properties of the coated film, a spectrophotometer (Shimadzu) and a contrast meter (CT-1, Tsubosaka Electric Co., Ltd.) were used. The measured results are shown in the following Table 1.
100 g pigment (used pigments are summarized in the following table)
1000 g PGMEA
2 g Solsperse® 5000 (Lubrizol)
20 g Ajisper® PB821 (Ajinomoto Fine Techno Co., Inc.)
5 g binder; Poly benzylmethacrylate-co-methacrylic acid (25 wt % in 1-methoxy-2-propyl-acetate), weight ratio of benzylmethacrylate:methacrylic acid=80:20
400 g zirconia bead (diameter 0.5 mm)

TABLE 1

| | |
|---|---|
| Optical properties | |
| (y = 0.600) | Viscosity |
| by C light | (cps) |

| Pigments | X | Y | CR | Initial | 1 week |
|---|---|---|---|---|---|
| E4GN-GT* | 0.281 | 53.0 | 100% | 18.5 | 35.0 |
| Comp. Ex. 1 | 0.280 | 53.3 | 60% | 15.2 | 25.0 |
| Comp. Ex. 2 | 0.280 | 52.5 | 54% | 19.0 | 46.2 |
| Ex. 1 | 0.316 | 61.0 | 110% | 14.0 | 15.4 |
| Ex. 2 | 0.312 | 60.4 | 139% | 18.0 | 20.5 |

*E4GN-GT: product manufactured by Viel aktiengesellschaft GmbH; pigment using melamine as a guest.

In Table 1, x is a color point and represents a deep color, as the value thereof increases, when y is maintained at 0.600. Accordingly, a pigment having a higher x value can be used at a smaller amount of pigment in order to represent color, the thickness of film decreases and brightness advantageously improves.

Y represents brightness and improves, as the value thereof increases, and CR represents a contrast ratio and is better as it increases.

Viscosity is a parameter that represents storage stability and represents superior storage stability, as an initial value and variation in value at 45° C. after one week becomes smaller.

Accordingly, as can be seen from Table 1, Examples 1 and 2 according to the present invention exhibit superior optical properties and viscosity, as compared to Comparative Example and commercially available products using melamine, or a derivative or polymer thereof as a guest compound.

### INDUSTRIAL APPLICABILITY

As apparent from the fore-going, the pigment composition according to the present invention exhibits improved color properties as well as superior stability and dispersability, thus being useful for color filters for displays and the like.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A pigment composition comprising a metal complex of azo compound of formula 1 containing at least one pyrimidine or a pyrimidine derivative: 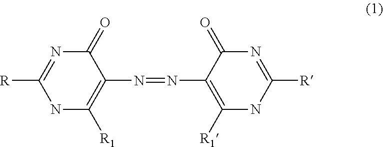
wherein R and R′ each independently represent OH, NH₂, NH—CN, acylamino or arylamino; and R₁ and R₁′ each independently represent —OH or —NH₂.

2. The pigment composition according to claim 1, wherein the pyrimidine or pyrimidine derivative is a compound of formula 2 below: 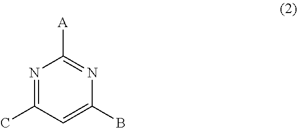
wherein A, B and C each independently represent C₁-C₅ alkyl, phenyl, —OH, —SH, —SOOH, —COOH, —NRR′, —O—R, or —O-Ph (in which R and R′ each independently represent hydrogen, C₁-C₅ alkyl or C₄-C₆ aryl).

3. The pigment composition according to claim 2, wherein the pyrimidine or pyrimidine derivative is a compound represented by the following formula 3: 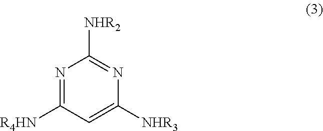
wherein R₂ to R₄ each independently represent hydrogen, C₁-C₄ alkyl or phenyl.

4. The pigment composition according to claim 3, wherein R₂ to R₄ are hydrogen.

5. The pigment composition according to claim 1, wherein the pyrimidine or pyrimidine derivative is contained in an amount of 5 to 300 parts by weight, based on 100 parts by weight of the metal complex excluding the guest compound.

6. The pigment composition according to claim 5, wherein the pyrimidine or pyrimidine derivative is contained at an amount of 10 to 200 parts by weight, based on 100 parts by weight of the metal complex excluding the guest compound.

7. The pigment composition according to claim 1, wherein the pigment composition has a primary particle size measured by a scanning electron microscope, lower than 60 nm.

8. The pigment composition according to claim 7, wherein the pigment composition has a primary particle size measured by a scanning electron microscope, lower than 40 nm.

9. The pigment composition according to claim 1, wherein the pigment composition comprises a mixture of is mixed with at least one organic solvent, a binder and/or a dispersant.

10. A photoresist comprising
the pigment composition according to claim 1 and optionally at least one other pigment;
at least one photocurable monomer;
at least one photoinitiator;
an organic solvent;
a binder;
an optional dispersant; and
an optional further additive.

11. A method for producing a color filter for displays comprising:
(a) grinding the pigment composition according to claim 1 in an organic solvent in the presence of a binder and dispersant;
(b) treating the ground substance obtained in step (a) in the presence of a photocurable monomer, a photoreactive initiator, a binder and a solvent to form a photoresist;
(c) applying the photoresist to a substrate by a roller, spray, spin, dip or air knife coating method; and
(d) irradiating the substrate through a photomask, followed by curing and developing to form a color filter.

12. A color filter comprising the pigment composition according to claim 1.

13. A display comprising at least one of the color filter according to claim 12.
